(19) United States
(12) Patent Application Publication
(10) Pub. No.: US 2026/0206633 A1
(43) Pub. Date: Jul. 16, 2026

(54) SEMICONDUCTOR DEVICE

(71) Applicant: ROHM CO., LTD., Kyoto (JP)

(72) Inventor: Tadayuki SAKAMOTO, Kyoto (JP)

(21) Appl. No.: 19/443,565

(22) Filed: Jan. 8, 2026

(30) Foreign Application Priority Data
Jan. 15, 2025 (JP) 2025-005427

(51) Int. Cl. H10W 72/50; H10W 70/40; H10W 74/10; H10W 90/00

(52) U.S. Cl. CPC H10W 72/541; H10W 70/421; H10W 74/111; H10W 90/756

(57) ABSTRACT

A semiconductor device includes: a first lead having a first surface facing one side in a thickness direction; a semiconductor element mounted on the first surface and including a plurality of electrodes; one or more second leads electrically connected to the semiconductor element; a sealing resin configured to cover the semiconductor element and at least a portion of each of the first lead and the one or more second leads; one or more conductors; first wires connected to the electrodes and the conductors; and second wires connected to the second leads, wherein a conductive path between the electrodes and the second leads includes the first wires, the conductors, and the second wires.

### CROSS-REFERENCE TO RELATED APPLICATION

This application is based upon and claims the benefit of priority from Japanese Patent Application No. 2025-005427, filed on January 15, 2025, the entire contents of which are incorporated herein by reference.

### TECHNICAL FIELD

The present disclosure relates to a semiconductor device.

### BACKGROUND

In the related art, there is known an example of a conventional semiconductor device. The semiconductor device includes a die pad, a semiconductor element, a plurality of leads, a plurality of wires, and a sealing resin. The semiconductor element is mounted on the die pad. The semiconductor element is individually connected to the plurality of leads via the plurality of wires. The sealing resin covers the semiconductor element and the plurality of wires, as well as a portion of each of the die pad and the plurality of leads. The arrangement of the semiconductor element and the plurality of leads may be set in various ways. Depending on the arrangement of the semiconductor element and the plurality of leads, the length of the plurality of wires may become long. As the length of the wires increases, interference may occur with adjacent wires, semiconductor elements, and the like.

### BRIEF DESCRIPTION OF DRAWINGS

The accompanying drawings, which are incorporated in and constitute a part of the specification, illustrate embodiments of the present disclosure.

FIG. 1 is a plan view showing a semiconductor device according to a first embodiment of the present disclosure.

FIG. 2 is a bottom view showing the semiconductor device according to the first embodiment of the present disclosure.

FIG. 3 is a cross-sectional view taken along line III-III in FIG. 1.

FIG. 4 is a cross-sectional view taken along line IV-IV in FIG. 1.

FIG. 5 is a cross-sectional view taken along line V-V in FIG. 1.

FIG. 6 is a cross-sectional view taken along line VI-VI in FIG. 1.

FIG. 7 is a plan view showing a semiconductor device according to a second embodiment of the present disclosure.

FIG. 8 is a cross-sectional view taken along line VIII-VIII in FIG. 7.

FIG. 9 is a plan view showing a semiconductor device according to a third embodiment of the present disclosure.

FIG. 10 is a cross-sectional view taken along line X-X in FIG. 9.

FIG. 11 is a cross-sectional view showing a modification of the semiconductor device according to the third embodiment of the present disclosure.

FIG. 12 is a plan view showing a semiconductor device according to a fourth embodiment of the present disclosure.

FIG. 13 is a bottom view showing the semiconductor device according to the fourth embodiment of the present disclosure.

FIG. 14 is a cross-sectional view taken along line XIV-XIV in FIG. 12.

FIG. 15 is a plan view showing a semiconductor device according to a fifth embodiment of the present disclosure.

FIG. 16 is a bottom view showing the semiconductor device according to the fifth embodiment of the present disclosure.

FIG. 17 is a cross-sectional view taken along line XVII-XVII in FIG. 15.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

The terms "first," "second," "third," etc. in this disclosure are used merely for identification purposes and are not intended to impose any ranking on their objects.

In the present disclosure, unless otherwise specified, "a certain object A is formed in a certain object B" and "a certain object A is formed on a certain object B" include "a certain object A is formed directly in a certain object B" and "a certain object A is formed in a certain object B with another object interposed between the certain object A and the certain object B." Similarly, unless otherwise specified, "a certain object A is arranged in a certain object B" and "a certain object A is arranged on a certain object B" include "a certain object A is arranged directly in a certain object B" and "a certain object A is arranged in a certain object B with another object interposed between the certain object A and the certain object B." Similarly, unless otherwise specified, "a certain object A is located on a certain object B" includes "a certain object A is located on a certain object B with the certain object A in contact with the certain object B" and "a certain object A is located on a certain object B with another object interposed between the certain object A and the certain object B." Further, unless otherwise specified, "an object A overlaps with an object B when viewed in a certain direction" includes "an object A overlaps with the entirety of an object B" and "an object A overlaps with a part of an object B." In addition, in the present disclosure, "a surface A faces a direction B (one side or the other side of the direction B)" is not limited to a case where the angle of a surface A with respect to a direction B is 90°, but also includes a case where a surface A is inclined with respect to a direction B.

### First Embodiment

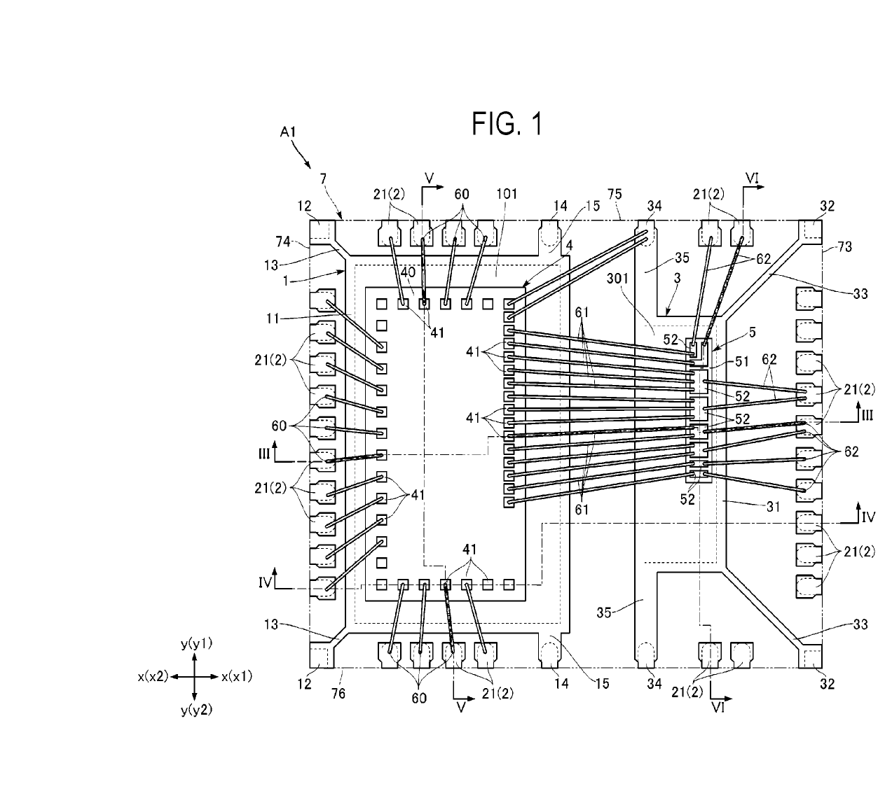

FIGS. 1 to 6 show a semiconductor device according to a first embodiment of the present disclosure. A semiconductor device A1 of this embodiment includes a first lead 1, a plurality of second leads 2, a third lead 3, a semiconductor element 4, a relay member 5 (e.g., first relay), a plurality of wires 60, a plurality of first wires 61, a plurality of second wires 62, and a sealing resin 7.

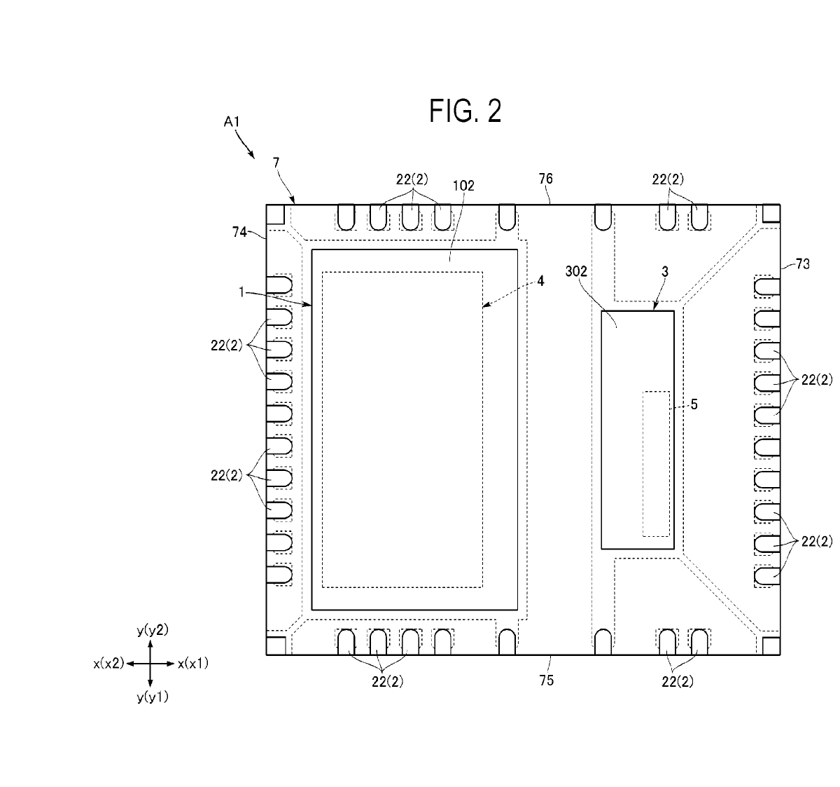

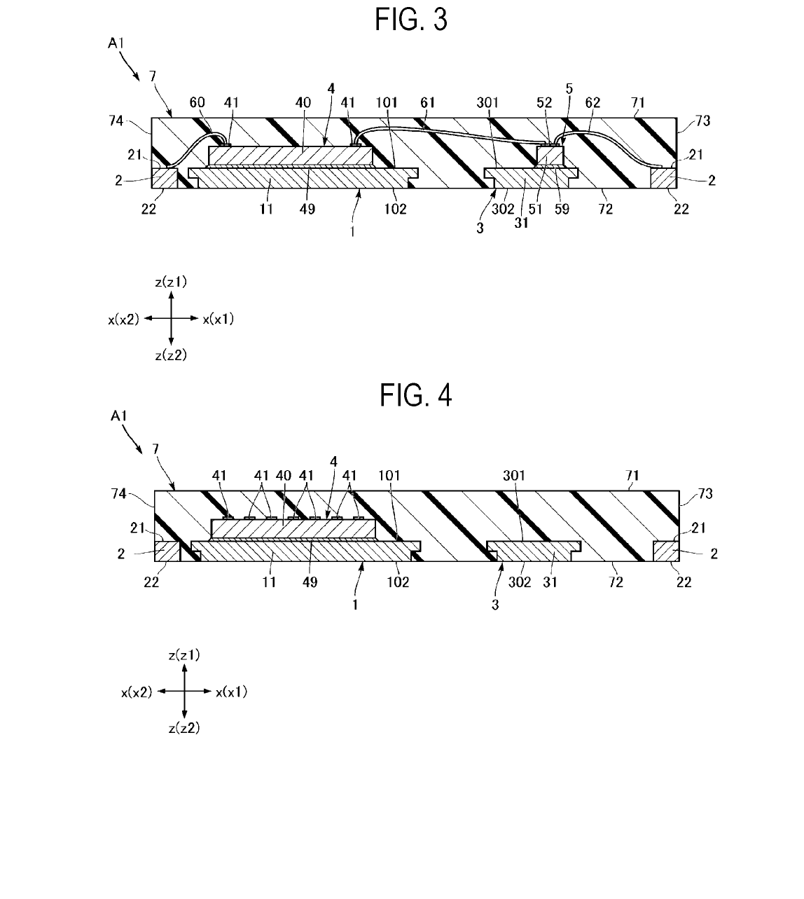

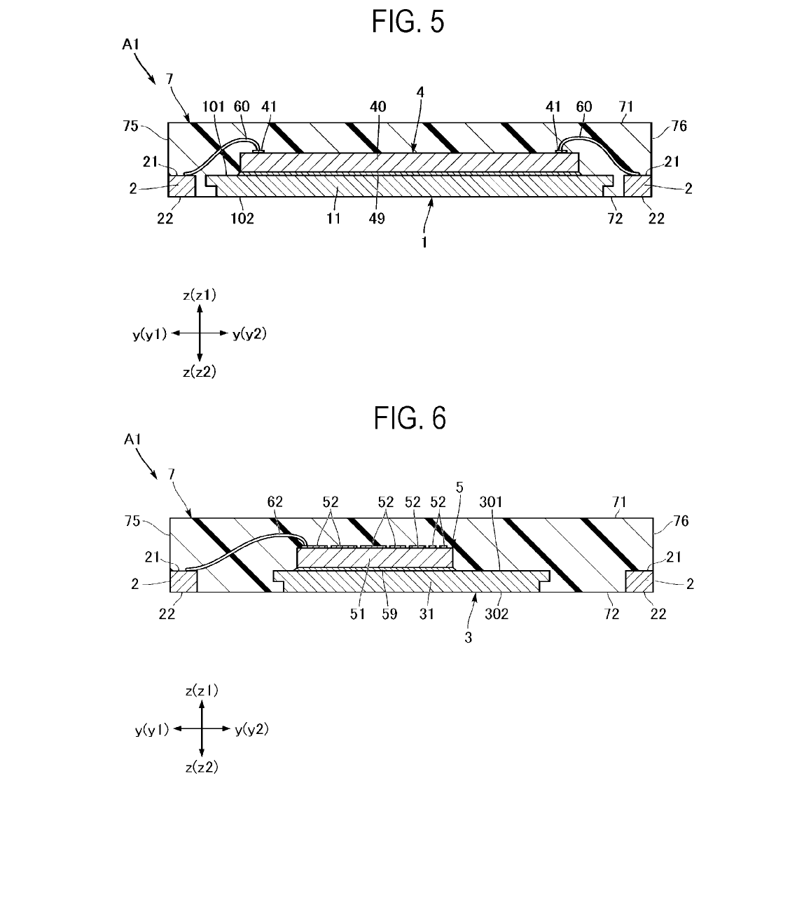

FIG. 1 is a plan view showing the semiconductor device A1, as seen through the sealing resin 7. FIG. 2 is a bottom view showing the semiconductor device A1. FIG. 3 is a cross-sectional view taken along line III-III in FIG. 1. FIG. 4 is a cross-sectional view taken along line IV-IV in FIG. 1. FIG. 5 is a cross-sectional view taken along line V-V in FIG. 1. FIG. 6 is a cross-sectional view taken along line VI-VI in FIG. 1. In FIG. 1, the outline of the sealing resin 7 is indicated by an imaginary line (two-dot chain line). In FIG. 4, the wires 60 are omitted.

In the description of the semiconductor device A1, the thickness direction (direction in a plan view) of the first lead 1 is an example of a "thickness direction" in the present disclosure and is referred to as a "thickness direction z." The direction perpendicular to the thickness direction z is an example of a "first direction" in the present disclosure and is referred to as a "first direction x." The direction perpendicular to both the thickness direction z and the first direction x is an example of a "second direction" in the present disclosure and is referred to as a "second direction y." Further, one side in the thickness direction z corresponds to the "one side in a thickness direction" in the present disclosure and is referred to as the "z1 side in the thickness direction z." The other side in the thickness direction z corresponds to the "other side in a thickness direction" in the present disclosure and is referred to as the "z2 side in the thickness direction z." One side in the first direction x corresponds to the "one side in a first direction" in the present disclosure and is referred to as the "x1 side in the first direction x." The other side in the first direction x corresponds to the "other side in a first direction" in the present disclosure and is referred to as the "x2 side in the first direction x." One side in the second direction y is referred to as the "y1 side in the second direction y," and the other side in the second direction y is referred to as the "y2 side in the second direction y."

The electrical function and package structure, such as the external shape, of the semiconductor device A1 are not particularly limited. In the illustrated example, the semiconductor device A1 is, for example, a QFN (Quad Flat Non-leaded package). In the illustrated example, the semiconductor device A1 is rectangular when viewed in the thickness direction z. The size of the semiconductor device A1 when viewed in the thickness direction z is not particularly limited, and for example, the size in the first direction x or the second direction y is approximately 6 mm or more and 10 mm or less.

The sealing resin 7 covers at least portions of the first lead 1, the second leads 2, and the third lead 3, as well as the semiconductor element 4. The sealing resin7 has electrical insulation properties. The sealing resin 7 may contain, for example, an epoxy resin, and may further contain a plurality of granular fillers (not shown).

The specific shape of the sealing resin 7 is not particularly limited, and is rectangular in the illustrated example when viewed in the thickness direction z. In the illustrated example, the sealing resin 7 has a first resin surface 71, a second resin surface 72, a third resin surface 73, a fourth resin surface 74, a fifth resin surface 75, and a sixth resin surface 76.

The first resin surface 71 is a surface facing the z1 side in the thickness direction z and is, for example, a flat surface. The second resin surface 72 is a surface facing the z2 side in the thickness direction z and is, for example, a flat surface. The third resin surface 73 is a surface facing the x1 side in the first direction x and is, for example, a flat surface. The fourth resin surface 74 is a surface facing the x2 side in the first direction x and is, for example, a flat surface. The fifth resin surface 75 is a surface facing the y1 side in the second direction y and is, for example, a flat surface. The sixth resin surface 76 is a surface facing the y2 side in the second direction y and is, for example, a flat surface.

The first lead 1 is a lead on which the semiconductor element 4 is mounted. The first lead 1 contains a metal such as Cu (copper), Ni (nickel), or Fe (iron), or an alloy thereof. In this embodiment, the first lead 1 mainly contains Cu (copper).

The first lead 1 has a first surface 101 and a second surface 102. The first surface 101 faces the z1 side in the thickness direction z and is, for example, a flat surface. The first surface 101 is covered with the sealing resin 7. The second surface 102 faces the z2 side in the thickness direction z and is, for example, a flat surface. The second surface 102 is exposed from the second resin surface 72. In the illustrated example, the second surface 102 is flush with the second resin surface 72.

As shown in FIG. 1 and other figures, the first lead 1 in the illustrated example includes an island portion 11, a plurality of corner portions 12, a plurality of connecting portions 13, a plurality of pad portions 14, and a plurality of connecting portions 15.

The island portion 11 is positioned offset toward the x2 side in the first direction x with respect to the contour of the semiconductor device A1 as a reference when viewed in the thickness direction z. The island portion 11 has a rectangular shape with the sides thereof extending along both the first direction x and the second direction y, respectively, when viewed in the thickness direction z.

The plurality of corner portions 12 are arranged in at least one of the four corners of the first resin surface 71. There is no limitation on the number of the plurality of corner portions 12, and in the illustrated example, there are two corner portions 12. One corner portion 12 is arranged at a corner of the first resin surface 71 on the x2 side in the first direction x and the y1 side in the second direction y. One corner portion 12 is exposed from the fourth resin surface 74 and the fifth resin surface 75. The other corner portion 12 is arranged at a corner of the first resin surface 71 on the x2 side in the first direction x and the y2 side in the second direction y. The other corner portion 12 is exposed from the fourth resin surface 74 and the sixth resin surface 76.

The plurality of connecting portions 13 individually connect the island portion 11 to the plurality of corner portions 12. In the illustrated example, the number of the plurality of connecting portions 13 is two.

The plurality of pad portions 14 are spaced apart from the island portion 11 in the second direction y. There is no limitation on the number of the plurality of pad portions 14, and in the illustrated example, there are two pad portions 14. One pad portion 14 is located on the y1 side of the island portion 11 in the second direction y. The other pad portion 14 is located on the y2 side of the island portion 11 in the second direction y.

The plurality of connecting portions 15 individually connect the island portion 11 to the plurality of pad portions 14. In the illustrated example, the number of the plurality of connecting portions 15 is two.

The plurality of second leads 2 are spaced apart from the first lead 1 when viewed in the thickness direction z. The plurality of second leads 2 contain, for example, a metal such as Cu (copper), Ni (nickel), or Fe (iron), or an alloy thereof. In this embodiment, the second leads 2 mainly contain Cu (copper). The arrangement of the second leads 2 is not particularly limited. In the illustrated example, the plurality of second leads 2 include a plurality of second leads 2 located on the x1 side of the island portion 11 and the island portion 31 (described later) in the first direction x and arranged in the second direction y. The plurality of second leads 2 further include a plurality of second leads 2 located on the x2 side of the island portion 11 in the first direction x and arranged in the second direction y. The plurality of second leads 2 further include a plurality of second leads 2 located on the y1 side of the island portion 11 in the second direction y and arranged in the first direction x. The plurality of second leads 2 further include a plurality of second leads 2 on the y2 side of the island portion 11 in the second direction y and arranged in the first direction x.

In the illustrated example, the second lead 2 includes a pad portion 21 and a terminal portion 22. The pad portion 21 faces the z1 side in the thickness direction z and is covered with the sealing resin 7. The terminal portion 22 is exposed from the sealing resin 7 and is used as a terminal surface, for example, when mounting the semiconductor device A1. In the illustrated example, the terminal portion 22 faces the z2 side in the thickness direction z and is exposed from the second resin surface 72.

The semiconductor element 4 is a component that performs the main electrical function of the semiconductor device A1. In this embodiment, the number of semiconductor elements 4 is one, but the number of semiconductor elements 4 is not particularly limited. The semiconductor device of the present disclosure may be configured to include a plurality of semiconductor elements 4. The size of the semiconductor element 4 as viewed in the thickness direction z is not particularly limited, and the size in the first direction x or the second direction y is, for example, approximately 1 mm or more and 5 mm or less.

There is no limitation on the specific configuration of the semiconductor element 4. The semiconductor element 4 may be, for example, a circuit element collectively referred to as an LSI (Large Scale Integration) or an IC (Integrated Circuit), or may be a functional element such as a MOSFET (Metal-Oxide-Semiconductor Field Effect Transistor). The semiconductor element 4 includes an element body 40 and a plurality of electrodes 41.

The element body 40 contains a semiconductor material such as Si (silicon). In the illustrated example, the element body 40 has a rectangular shape when viewed in the thickness direction z. The element body 40 includes, for example, a circuit (not shown) that realizes the electrical function that the semiconductor element 4 should perform.

The plurality of electrodes 41 are located on the z1 side of the element body 40 in the thickness direction z. The size, shape, arrangement, etc. of the plurality of electrodes 41 are not particularly limited. In the illustrated example, the plurality of electrodes 41 are arranged along the four sides of the element body 40.

The semiconductor element 4 is mounted on the first surface 101 of the island portion 11. In the illustrated example, the semiconductor element 4 is bonded to the first surface 101 by a bonding material 49. The bonding material 49 may be, for example, a conductive bonding material such as solder or Ag (silver) paste, or may be an insulating bonding material.

In this embodiment, the third lead 3 is a lead on which the first relay member 5 is mounted. The third lead 3 is located on the x1 side of the first lead 1 in the first direction x. The third lead 3 contains, for example, a metal such as Cu (copper), Ni (nickel), or Fe (iron), or an alloy thereof. In this embodiment, the third lead 3 mainly contains Cu (copper).

The third lead 3 has a third surface 301 and a fourth surface 302. The third surface 301 is a surface facing the z1 side in the thickness direction z and is, for example, a flat surface. The third surface 301 is covered with the sealing resin 7. The fourth surface 302 is a surface facing the z2 side in the thickness direction z and is, for example, a flat surface. The fourth surface 302 is exposed from the second resin surface 72. In the illustrated example, the fourth surface 302 is flush with the second resin surface 72.

As shown in FIG. 1 and other figures, the third lead 3 in the illustrated example includes an island portion 31, a plurality of corner portions 32, a plurality of connecting portions 33, a plurality of pad portions 34, and a plurality of connecting portions 35.

The island portion 31 is positioned offset toward the x1 side in the first direction x with respect to the contour of the semiconductor device A1 when viewed in the thickness direction z. The island portion 31 is positioned on the x1 side of the island portion 11 in the first direction x. When viewed in the thickness direction z, the island portion 31 has a rectangular shape with the sides thereof extending along both the first direction x and the second direction y, respectively.

The plurality of corner portions 32 are arranged in at least one of the four corners of the first resin surface 71. The number of the plurality of corner portions 32 is not particularly limited, and in the illustrated example, there are two corner portions 32. One corner portion 32 is arranged at a corner of the first resin surface 71 on the x1 side in the first direction x and the y1 side in the second direction y. One corner portion 32 is exposed from the third resin surface 73 and the fifth resin surface 75. The other corner portion 32 is arranged at a corner of the first resin surface 71 on the x1 side in the first direction x and the y2 side in the second direction y. The other corner portion 32 is exposed from the third resin surface 73 and the sixth resin surface 76.

The plurality of connecting portions 33 individually connect the island portion 31 to the plurality of corner portions 32. In the illustrated example, the number of the plurality of connecting portions 33 is two.

The pad portions 34 are spaced apart from the island portion 31 in the second direction y. There is no limitation on the number of the plurality of pad portions 34, and in the illustrated example, there are two pad portions 34. One pad portion 34 is located on the y1 side of the island portion 31 in the second direction y. The other pad portion 34 is located on the y2 side of the island portion 31 in the second direction y.

The plurality of connecting portions 35 individually connect the island portion 31 to the plurality of pad portions 34. In the illustrated example, the number of the plurality of connecting portions 35 is two.

The relay member 5 is spaced apart from the semiconductor element 4. The relay member 5 includes an insulating layer 51 and a plurality of wiring portions 52.

The insulating layer 51 contains a material that exhibits electrical insulation, including a semiconductor material such as silicon (Si), a resin, or a ceramic. In the illustrated example, the insulating layer 51 contains, for example, silicon (Si), which is a semiconductor material. The size of the insulating layer 51 is not particularly limited, and the thickness (dimension in the thickness direction z) is, for example, approximately 100 μm or more and 400 μm or less.

The plurality of wiring portions 52 are arranged on the insulating layer 51. The plurality of wiring portions 52 may contain a metal such as Al (aluminum), Ag (silver), Cu (copper), Au (gold), or Pd (palladium), or an alloy thereof. In the illustrated example, the plurality of wiring portions 52 are laminated on the surface of the insulating layer 51 facing the z1 side in the thickness direction z. The specific shape and arrangement of the plurality of wiring portions 52 are not particularly limited. The wiring portions 52 may be included in the conductive path between the electrode 41 and the second lead 2. The wiring portions 52 correspond to the "conductor" in the present disclosure.

In the illustrated example, the semiconductor device A1 includes one relay member 5. The relay member 5 is mounted on the third surface 301 of the island portion 31. In the illustrated example, the relay member 5 is bonded to the third surface 301 by a bonding material 59. The bonding material 59 may be a conductive bonding material, an insulating bonding material, or the like.

The relay member 5 is located on the x1 side of the semiconductor element 4 in the first direction x. In the illustrated example, the relay member 5 is located offset toward the x1 side in the first direction x in the island portion 31 (third lead 3) when viewed in the thickness direction z. The relay member 5 has a rectangular shape when viewed in the thickness direction z and is elongated in the second direction y. The relay member 5 overlaps with the semiconductor element 4 when viewed in the first direction x.

The plurality of wires 60 contain a metal such as gold (Au), copper (Cu), or aluminum (Al), or an alloy thereof. The diameter of the wires 60 is not particularly limited and is, for example, about 10 μm or more and 30 μm or less. The wires 60 are connected to the electrodes 41 and the pad portions 21 (second leads 2).

The plurality of first wires 61 are included in the conductive path between the electrode 41 and the second lead 2. The first wires 61 contain a metal such as Au (gold), Cu (copper), or Al (aluminum), or an alloy thereof. The diameter of the first wires 61 is not particularly limited and is, for example, approximately 10 μm or more and 30 μm or less. The first wires 61 are connected to the electrode 41 and the wiring portion 52.

The plurality of second wires 62 are included in the conductive path between the electrode 41 and the second lead 2. The second wires 62 contain a metal such as Au (gold), Cu (copper), or Al (aluminum), or an alloy thereof. The diameter of the second wires 62 is not particularly limited and is, for example, approximately 10 μm or more and 30 μm or less. The second wires 62 are connected to the wiring portion 52 and the pad portion 21 (second lead 2). Specifically, the second wires 62 are connected to the wiring portion 52 to which the first wires 61 are connected, and to the pad portion 21 (second lead 2).

The conductive path between the plurality of electrodes 41 and the second lead 2 included in the semiconductor device A1 includes a configuration constituted by the first wires 61, one wiring portion 52, and the second wires 62.

In the illustrated example, the conductive path includes a configuration in which the plurality of first wires 61 are connected to one wiring portion 52. Specifically, three first wires 61 are connected to some of the plurality of wiring portions 52. Two first wires 61 are connected to some other of the plurality of wiring portions 52.

In the illustrated example, the conductive path includes a configuration in which one pad portion 21 (second lead 2) is connected to the plurality of second wires 62. Specifically, two second wires 62 are connected to some of the plurality of pad portions 21 (second leads 2).

In the illustrated example, among the plurality of second leads 2, some of the second leads 2 to which the second wires 62 are connected are located on the x1 side of the relay member 5 in the first direction x. Furthermore, among the plurality of second leads 2, some other second leads 2 to which the second wires 62 are connected are spaced apart in the second direction y from the relay member 5 and are located on the y1 side of the relay member 5 in the second direction y.

Next, an operation of the semiconductor device A1 will be described.

According to this embodiment, the conductive path between the electrode 41 and the second lead 2 includes the first wires 61, the wiring portions 52 (conductor), and the second wires 62. Therefore, the lengths of the first wires 61 and the second wires 62 can be made shorter than when the electrode 41 and the second lead 2 are connected by a single first wire 61 or a single second wire 62. This reduces problems caused by the long lengths of the first wire 61, the second wire 62, etc. Examples of such problems include a problem in which, when a resin material is injected to form the sealing resin 7, due to the flow of the resin material, a long wire is bent and comes into contact with an adjacent wire. According to this embodiment, such wire contact can be suppressed.

The semiconductor device A1 includes a relay member 5. The relay member 5 includes an insulating layer 51 and a wiring portion 52 located on the insulating layer 51. In this embodiment, the first wire 61 and the second wire 62 are connected to the wiring portion 52. This makes it possible to set various conductive paths between the plurality of second leads 2 and the plurality of electrodes 41 using the relay member 5, without changing the semiconductor element 4 and the first leads 1. Accordingly, various semiconductor elements 4 can be used without changing the external dimensions of the semiconductor device A1, the arrangement of the plurality of second leads 2, and the like.

The semiconductor device A1 includes a configuration in which the plurality of first wires 61 are connected to one wiring portion 52. This makes it possible to reduce the parasitic inductance of the first wires 61.

In the semiconductor device A1, the plurality of second wires 62 are connected to one second lead 2. The relay member 5 is located offset toward the x1 side of the island portion 31 (third lead 3) in the first direction x when viewed in the thickness direction z. With this configuration, the length of the second wires 62 connected to the wiring portion 52 and the second lead 2 can be made shorter than the length of the first wires 61 connected to the electrode 41 and the wiring portion 52. This makes it possible to reduce the parasitic inductance of the second wires 62.

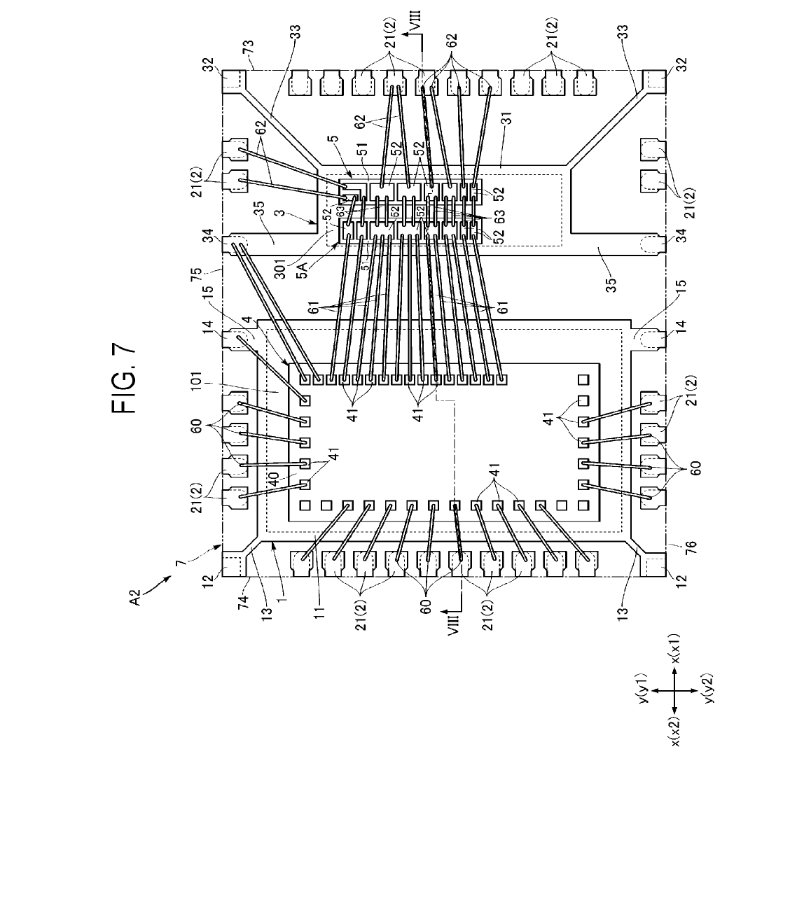

FIGS. 7 to 17 show other embodiments of the present disclosure. In these figures, elements that are the same as or similar to those in the above-described embodiment are denoted by the same reference numerals. Furthermore, configurations of various parts in each embodiment and each modification can be combined with each other as appropriate within the scope that does not cause technical contradictions.

### Second Embodiment

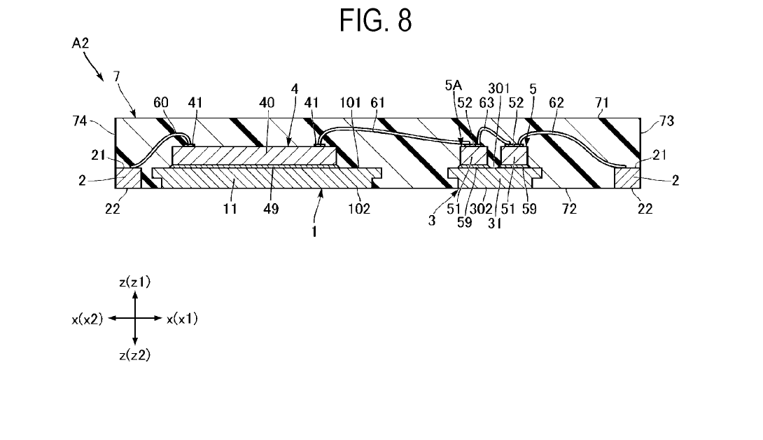

FIGS. 7 and 8 show a semiconductor device A2 according to a second embodiment of the present disclosure. FIG. 7 is a plan view of the semiconductor device A2, as seen through the sealing resin 7. FIG. 8 is a cross-sectional view taken along line VIII-VIII in FIG. 7. In FIG. 7, the contour of the sealing resin 7 is indicated by an imaginary line (two-dot chain line).

The semiconductor device A2 of this embodiment is additionally provided with a relay member 5A and a plurality of third wires 63 compared to the semiconductor device A1.

The relay member 5A is located on the x2 side of the relay member 5 in the first direction x. The relay member 5A is located between the semiconductor element 4 and the relay member 5 in the first direction x. The relay member 5A is mounted on the third surface 301 of the island portion 31. In the illustrated example, the relay member 5A is bonded to the third surface 301 via a bonding material 59. The bonding material 59 may be a conductive bonding material, an insulating bonding material, or the like. The relay member 5A has a rectangular shape when viewed in the thickness direction z and is elongated in the second direction y. The relay member 5A overlaps with the semiconductor element 4 when viewed in the first direction x. The relay member 5A includes an insulating layer 51 and a plurality of wiring portions 52. The relay member 5A corresponds to an "additional relay member" (e.g., second relay) in the present disclosure.

The insulating layer 51 of the relay member 5A contains an electrically insulating material including a semiconductor material such as silicon (Si), a resin, a ceramic, and the like. In the illustrated example, the insulating layer 51 contains, for example, silicon (Si), which is a semiconductor material.

The plurality of wiring portions 52 of the relay member 5A are arranged on the insulating layer 51. The plurality of wiring portions 52 may contain a metal such as Al (aluminum), Ag (silver), Cu (copper), Au (gold), or Pd (palladium), or an alloy thereof. In the illustrated example, the plurality of wiring portions 52 are stacked on the surface of the insulating layer 51 facing the z1 side in the thickness direction z. The specific shape and arrangement of the plurality of wiring portions 52 are not particularly limited. The wiring portions 52 of the relay member 5A may be included in the conductive path between the electrode 41 and the second lead 2. The wiring portions 52 of the relay member 5A correspond to the "conductor" in the present disclosure.

In this embodiment, each of the plurality of first wires 61 is connected to the electrode 41 and the wiring portions 52 of the relay member 5A.

The plurality of third wires 63 are included in the conductive path between the electrode 41 and the second lead 2. The third wires 63 contain a metal such as Au (gold), Cu (copper), or Al (aluminum), or an alloy thereof. The diameter of the third wires 63 is not particularly limited and is, for example, approximately 10 μm or more and 30 μm or less. The third wires 63 are connected to the wiring portions 52 of the relay member 5A and the wiring portions 52 of the relay member 5. Specifically, the third wires 63 are connected to the wiring portions 52 of the relay member 5A to which the first wires 61 are connected, and to the wiring portions 52 of the relay member 5 to which the second wires 62 are connected.

According to this embodiment, the lengths of the first wires 61 and the second wires 62 can be shortened. Furthermore, by further including the third wires 63 in the conductive path between the electrode 41 and the second lead 2, the length of the wires can be further shortened, or the distance between the electrode 41 and the second lead 2 can be set to be further apart. As can be seen from this embodiment, there is no limitation on the number of wiring portions 52 and wires included in the conductive path between the electrode 41 and the second lead 2. In addition, the semiconductor device A2 achieves the same effects as those of the semiconductor device A1 within the same range of configuration as the semiconductor device A1 of the above-described embodiment.

### Third Embodiment

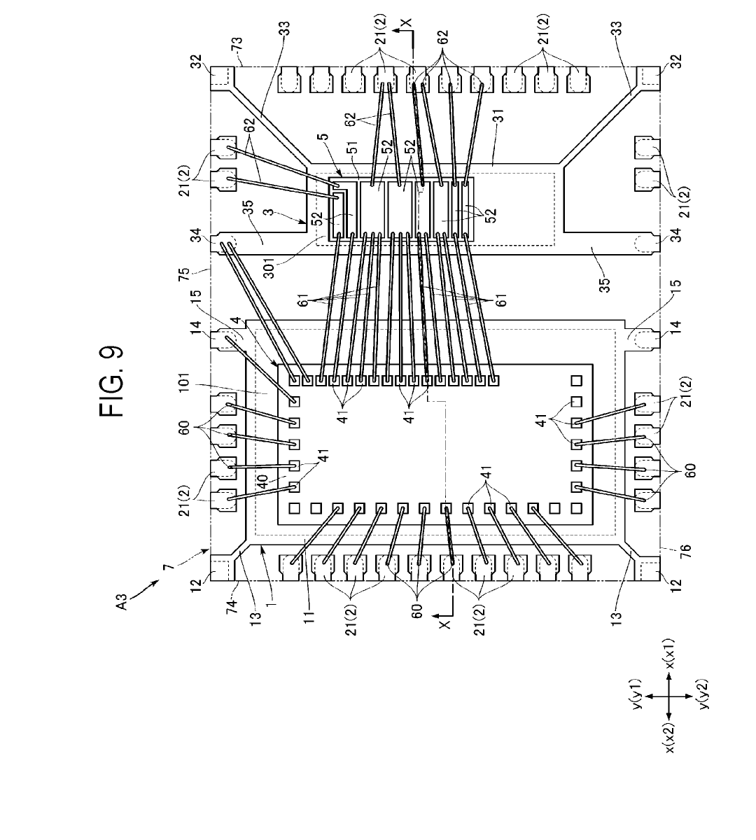

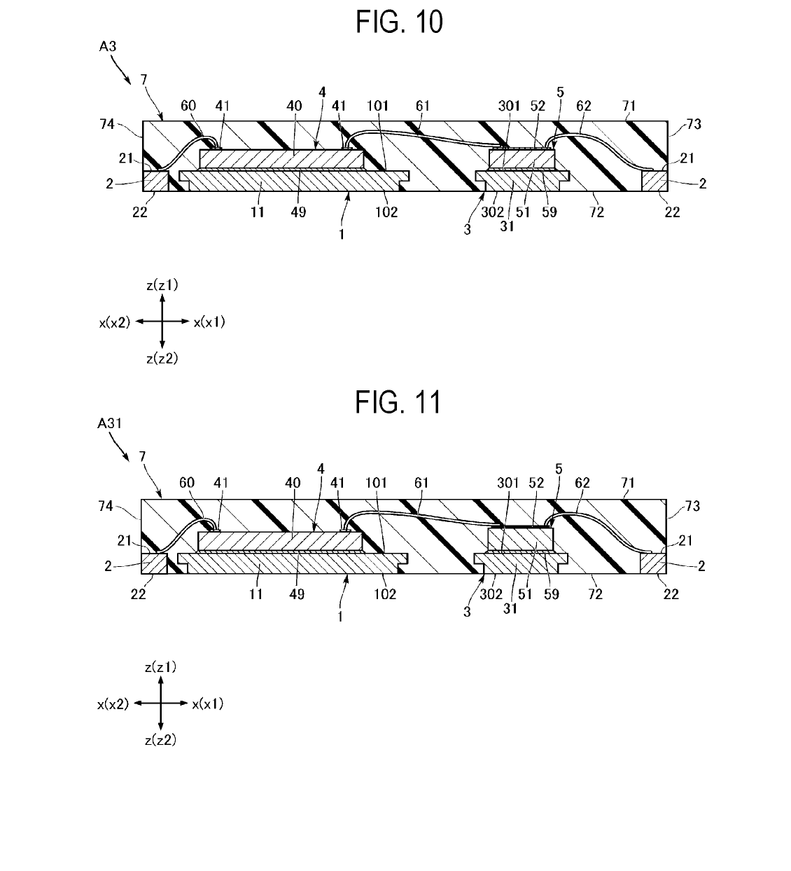

FIGS. 9 and 10 show a semiconductor device A3 according to a third embodiment of the present disclosure. FIG. 9 is a plan view of the semiconductor device A3, as seen through the sealing resin 7. FIG. 10 is a cross-sectional view taken along line X-X in FIG. 9. In FIG. 9, the contour of the sealing resin 7 is indicated by an imaginary line (two-dot chain line).

The semiconductor device A3 of this embodiment differs from the semiconductor device A1 in the configuration of the relay member 5. The relay member 5 of the semiconductor device A3 is longer in the first direction x than the relay member 5 of the semiconductor device A1. Each of the plurality of wiring portions 52 of the relay member 5 is elongated in the first direction x. The first wire 61 is connected to the end of the wiring portion 52 on the x2 side in the first direction x. The second wire 62 is connected to the end of the wiring portion 52 on the x1 side in the first direction x.

According to this embodiment, it is possible to shorten the lengths of the first wires 61 and the second wires 62. Furthermore, since the wiring portions 52 included in the conductive path between the electrode 41 and the second lead 2 are elongated in the first direction x, it is possible to further shorten the overall lengths of the first wires 61 and the second wires 62. In addition, the semiconductor device A3 achieves the same effects as those of the semiconductor device A1 within the same range of configuration as the semiconductor device A1 of the above-described embodiment.

### Modification of Third Embodiment

FIG. 11 shows a modification of the semiconductor device A3. FIG. 11 is a cross-sectional view of the semiconductor device A31 of this modification, corresponding to the cross-section shown in FIG. 10. In the semiconductor device A31, the insulating layer 51 is made of ceramics. Examples of ceramics that can be used to form the insulating layer 51 include AlN (aluminum nitride), Al₂O₃(alumina), and Si₃N₄ (silicon nitride). The size of the insulating layer 51 is not particularly limited, and the thickness (dimension in the thickness direction z) thereof is, for example, approximately 200 μm or more and 700 μm or less. The plurality of wiring portions 52 are, for example, wiring patterns formed on the insulating layer 51. The plurality of wiring portions 52 contain, for example, a metal such as Cu (copper).

According to this modification, it is possible to shorten the lengths of the first wires 61 and the second wires 62. Furthermore, since the wiring portions 52 included in the conductive path between the electrode 41 and the second lead 2 are elongated in the first direction x, it is possible to further shorten the overall lengths of the first wires 61 and the second wires 62. In addition, the semiconductor device A31 achieves the same effects as those of the semiconductor device A1 within the same range of configuration as the semiconductor device A1 of the above-described embodiment.

### Fourth Embodiment

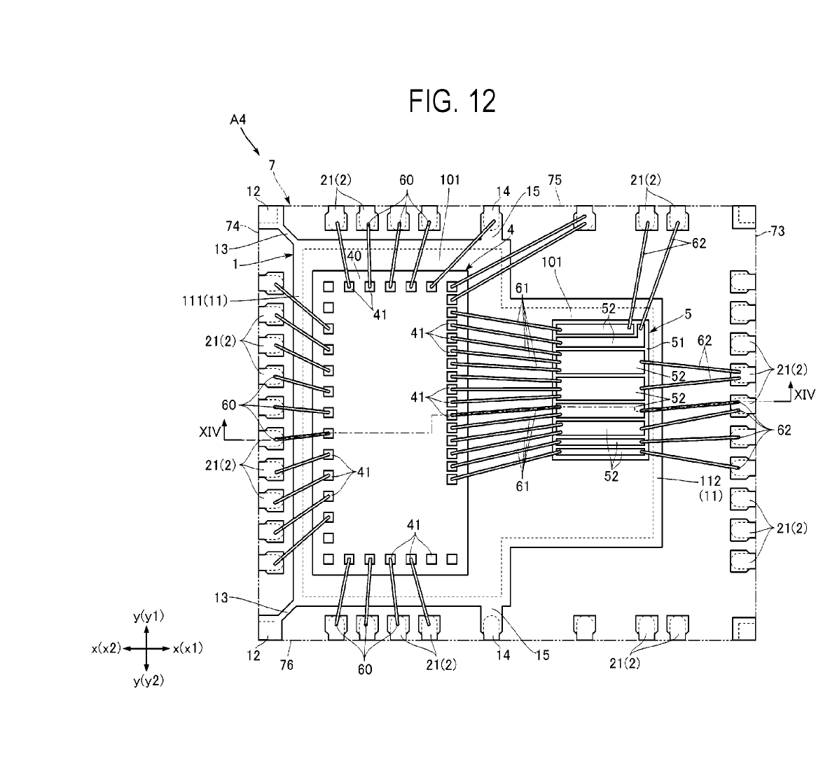

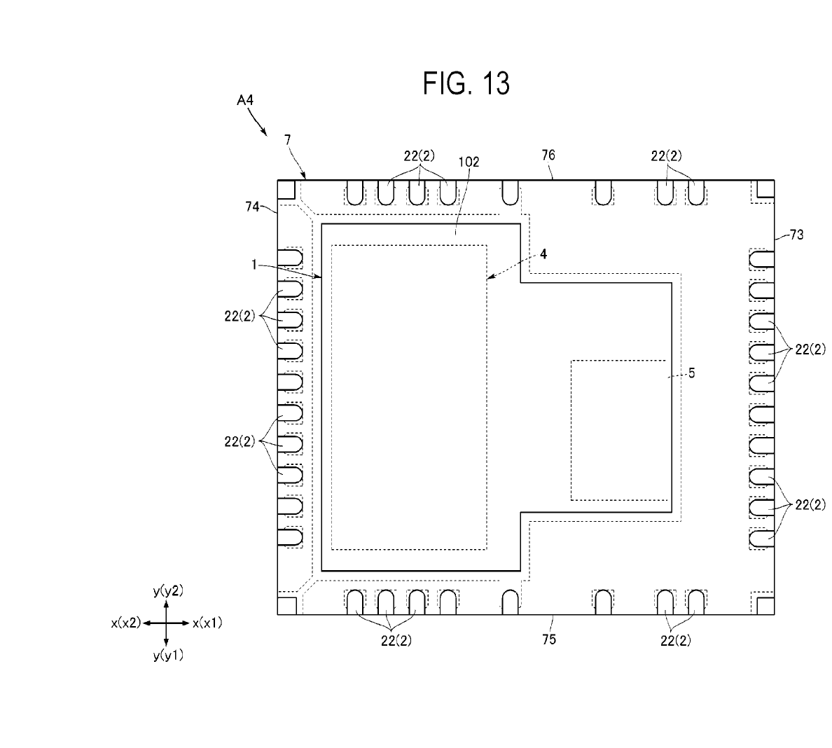

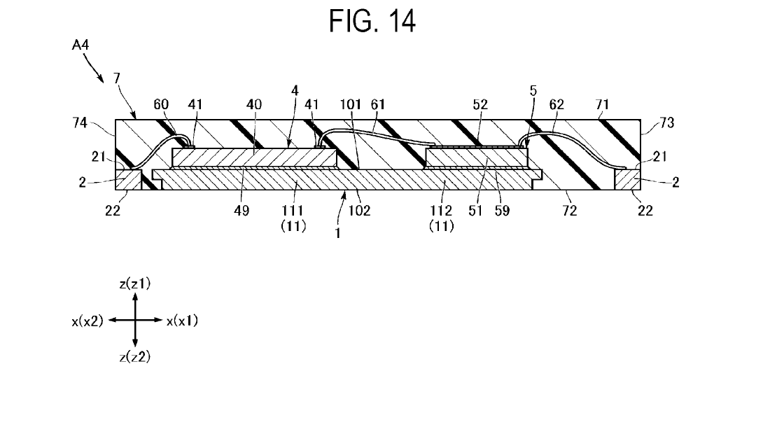

FIGS. 12 to 14 show a semiconductor device A4 according to a fourth embodiment of the present disclosure. FIG. 12 is a plan view of the semiconductor device A4, as seen through the sealing resin 7. FIG. 13 is a bottom view of the semiconductor device A4. FIG. 14 is a cross-sectional view taken along line XIV-XIV in FIG. 12. In FIG. 12, the contour of the sealing resin 7 is indicated by an imaginary line (two-dot chain line).

Compared to the semiconductor device A3, the semiconductor device A4 of this embodiment does not include a third lead 3 and the shape of the island portion 11 in the first lead 1 is different. In this embodiment, the island portion 11 includes a first portion 111 and a second portion 112. The second portion 112 is connected to the x1 side of the first portion 111 in the first direction x. Each of the first portion 111 and the second portion 112 has a rectangular shape when viewed in the thickness direction z. The semiconductor element 4 is mounted on the first surface 101 of the first portion 111 of the island portion 11. The relay member 5 is mounted on the first surface 101 of the second portion 112 of the island portion 11. In the illustrated example, the length of the second portion 112 in the second direction y is shorter than the length of the first portion 111 in the second direction y. The shape of the island portion 11 (first portion 111 and second portion 112) is not particularly limited, and for example, the length of the second portion 112 in the second direction y may be the same as the length of the first portion 111 in the second direction y.

According to this embodiment, it is possible to shorten the lengths of the first wires 61 and the second wires 62. Furthermore, since the wiring portions 52 included in the conductive path between the electrode 41 and the second lead 2 are elongated in the first direction x, it is possible to further shorten the overall lengths of the first wires 61 and the second wires 62. In addition, the semiconductor device A4 achieves the same effects as those of the semiconductor device A1 within the same range of configuration as the semiconductor device A1 of the above-described embodiment.

### Fifth Embodiment

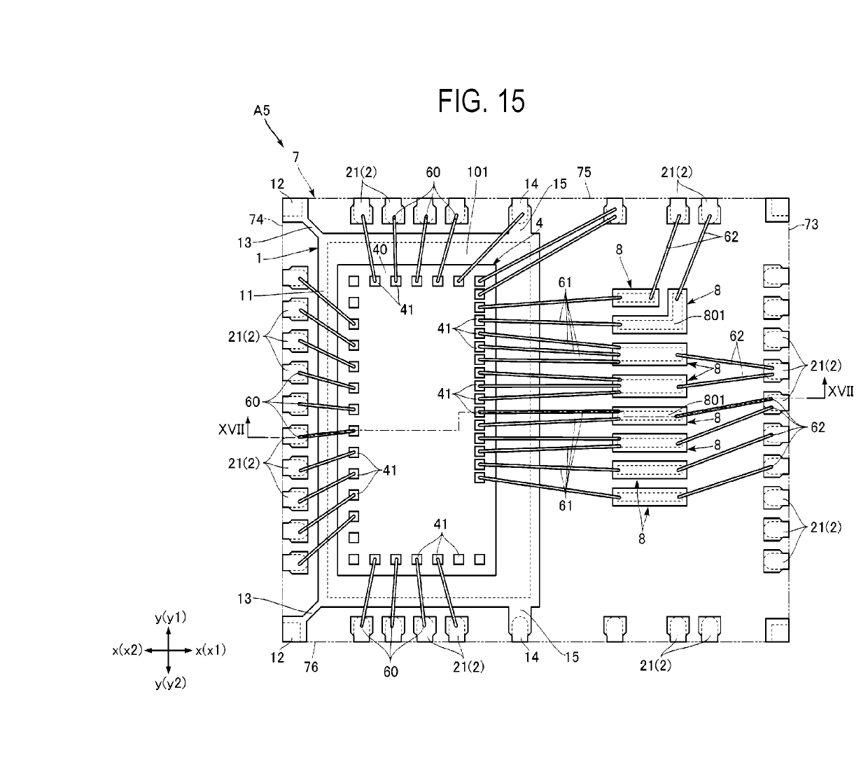

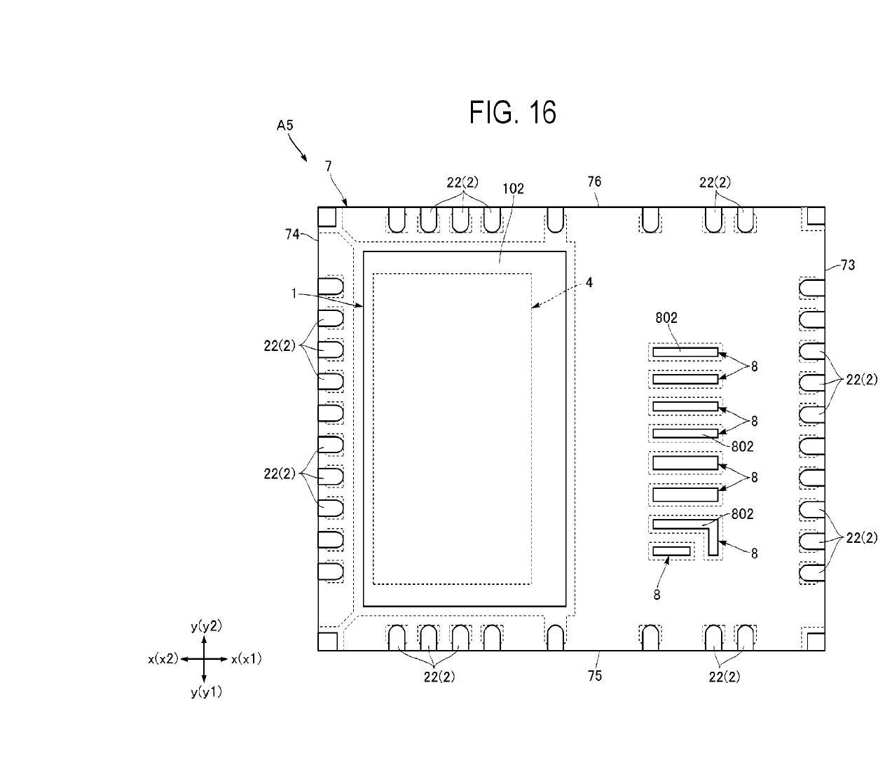

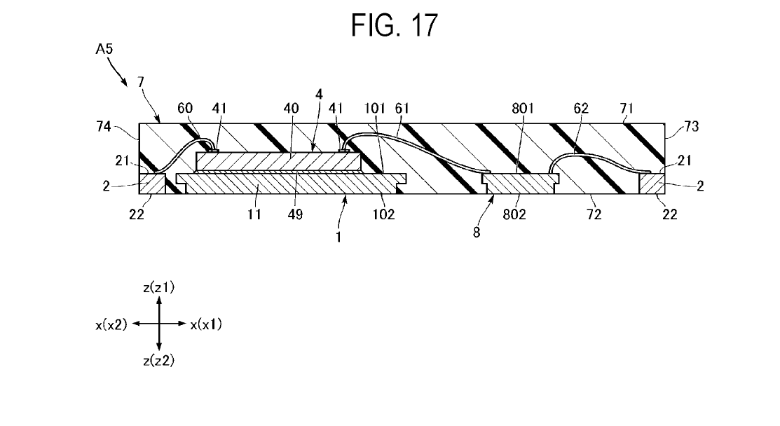

FIGS. 15 to 17 show a semiconductor device A5 according to a fifth embodiment of the present disclosure. FIG. 15 is a plan view of the semiconductor device A5, as seen through the sealing resin 7. FIG. 16 is a bottom view of the semiconductor device A5. FIG. 17 is a cross-sectional view taken along line XVII-XVII in FIG. 15. In FIG. 15, the contour of the sealing resin 7 is indicated by an imaginary line (two-dot chain line).

Unlike the semiconductor device A1, the semiconductor device A5 of this embodiment does not include the third lead 3 and the relay member 5, and includes a plurality of fourth leads 8 instead of the relay member 5. The plurality of fourth leads 8 are spaced apart from the first lead 1 and the plurality of second leads 2 when viewed in the thickness direction z. The plurality of fourth leads 8 are located on the x1 side of the first lead 1 in the first direction x. The plurality of fourth leads 8 contain, for example, a metal such as Cu (copper), Ni (nickel), or Fe (iron), or an alloy thereof. In this embodiment, the fourth leads 8 mainly contain Cu (copper). The arrangement of the plurality of fourth leads 8 is not particularly limited. In the illustrated example, the fourth leads 8 are elongated in the first direction x.

The fourth lead 8 has a fifth surface 801 and a sixth surface 802. The fifth surface 801 is a surface facing the z1 side in the thickness direction z and is, for example, a flat surface. The fifth surface 801 is covered with the sealing resin 7. The sixth surface 802 is a surface facing the z2 side in the thickness direction z and is, for example, a flat surface. The sixth surface 802 is exposed from the second resin surface 72. In the illustrated example, the sixth surface 802 is flush with the second resin surface 72.

The first wire 61 and the second wire 62 are connected to the fifth surface 801 of the fourth lead 8. The first wire 61 is connected to the end of the fourth lead 8 on the x2 side in the first direction x. The second wire 62 is connected to the end of the fourth lead 8 on the x1 side in the first direction x. The fourth lead 8 is included in the conductive path between the electrode 41 and the second lead 2. The fourth lead 8 corresponds to the "conductor" in the present disclosure.

According to this embodiment, it is possible to shorten the lengths of the first wires 61 and the second wires 62. Furthermore, since the fourth lead 8 included in the conductive path between the electrode 41 and the second lead 2 is elongated in the first direction x, it is possible to further shorten the overall lengths of the first wires 61 and the second wires 62. In addition, the semiconductor device A5 achieves the same effects as those of the semiconductor device A1 within the same range of configuration as the semiconductor device A1 of the above-described embodiment.

The semiconductor device according to the present disclosure is not limited to the above-described embodiments, and the specific configuration of each part of the semiconductor device according to the present disclosure may be freely modified in various ways.

The present disclosure comprises configurations set forth in the following supplementary notes.

### Supplementary Note 1

A semiconductor device (A1, A2, A3, A31, A4 or A5), includes:

a first lead (1) having a first surface (101) facing one side (z1 side) in a thickness direction (z);

a semiconductor element (4) mounted on the first surface (101) and including a plurality of electrodes (41);

one or more second leads (2) electrically connected to the semiconductor element (4);

a sealing resin (7) configured to cover the semiconductor element (4) and at least a portion of each of the first lead (1) and the one or more second leads (2);

one or more conductors (52 or 8);

first wires (61) connected to the electrodes (41) and the conductors (52 or 8); and second wires (62) connected to the second leads (2),

wherein a conductive path between the electrodes (41) and the second leads (2) includes the first wires (61), the conductors (52 or 8), and the second wires (62).

### Supplementary Note 2

The semiconductor device (A1, A2, A3, A31 or A4) of Supplementary Note 1, further includes a first relay (5), wherein the first relay (5) includes:

an insulating layer (51); and

the conductors (52) located on the insulating layer (51).

### Supplementary Note 3

The semiconductor device (A1, A2, A3 or A31) of Supplementary Note 2, further includes a third lead (3), wherein the third lead (3) has a third surface (301) facing one side (z1 side) in the thickness direction (z), and

wherein the first relay (5) is mounted on the third surface (301).

### Supplementary Note 4

The semiconductor device (A4) of Supplementary Note 2, wherein the first relay (5) is mounted on the first surface (101).

### Supplementary Note 5

The semiconductor device (A1, A3, A31, A4 or A5) of any one of Supplementary Notes 1 to 4, wherein the second wires (62) are connected to the conductors (52 or 8) to which the first wires (61) are connected.

### Supplementary Note 6

The semiconductor device (A1, A2, A3, A31, A4 or A5) of any one of Supplementary Notes 1 to 5, wherein the first wires (61) are connected to the conductors (52 or 8).

### Supplementary Note 7

The semiconductor device (A1, A2, A3, A31, A4 or A5) of any one of Supplementary Notes 1 to 6, wherein the second wires (62) are connected to the second leads (2).

### Supplementary Note 8

The semiconductor device (A2) of any one of Supplementary Notes 1 to 3, further includes third wires (63) connected to the conductors (52) to which the first wires (61) are connected,

wherein the conductive path further includes the third wires (63).

### Supplementary Note 9

The semiconductor device (A1, A2, A3, A31 or A4) of Supplementary Note 2, wherein the first relay (5) is located on one side (x1 side) of the semiconductor element (4) in a first direction (x) perpendicular to the thickness direction (z).

### Supplementary Note 10

The semiconductor device (A1 or A2) of Supplementary Note 3, wherein the third lead (3) is located on one side (x1 side) of the first lead (1) in a first direction (x) perpendicular to the thickness direction (z), and

wherein the first relay (5) is located on the third lead (3) offset toward one side (x1 side) in the first direction (x) when viewed in the thickness direction (z).

### Supplementary Note 11

The semiconductor device (A2) of Supplementary Note 10, further includes:

a second relay (5A) located on the other side (x2 side) of the first relay (5) in the first direction (x) and mounted on the third surface (301); and third wires (63),

wherein the first wires (61) are connected to the conductors (52) of the second relay (5A),

the third wires (63) are connected to the conductors (52) of the second relay (5A) and the conductors (52) of the first relay (5), and the conductive path further includes the third wires (63).

### Supplementary Note 12

The semiconductor device (A1, A2, A3, A31 or A4) of Supplementary Note 9, wherein the second leads (2) to which the second wires (62) are connected are located on one side (x1 side) of the first relay (5) in the first direction (x).

### Supplementary Note 13

The semiconductor device (A1, A2, A3, A31 or A4) of Supplementary Note 9 or 12, wherein the second leads (2) to which the second wires (62) are connected are located apart from the first relay (5) in a second direction (y) perpendicular to the thickness direction (z) and the first direction (x).

### Supplementary Note 14

The semiconductor device (A1, A2, A3, A31, A4) of any one of Supplementary Notes 2 to 4, wherein the insulating layer contains a semiconductor material.

### Supplementary Note 15

The semiconductor device (A31) of any one of Supplementary Notes 2 to 4, wherein the insulating layer contains ceramics.

### Supplementary Note 16

The semiconductor device (A5) of any one of Supplementary Notes 1 and 5 to 7, further includes one or more fourth leads (8), wherein the conductors include the fourth leads (8).

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device, comprising:
a first lead having a first surface facing one side in a thickness direction;
a semiconductor element mounted on the first surface and including a plurality of electrodes;
one or more second leads electrically connected to the semiconductor element;
a sealing resin configured to cover the semiconductor element and at least a portion of each of the first lead and the one or more second leads;
one or more conductors;
first wires connected to the electrodes and the conductors; and
second wires connected to the second leads,
wherein a conductive path between the electrodes and the second leads includes the first wires, the conductors, and the second wires.

2. The semiconductor device of claim 1, further comprising a first relay, wherein the first relay includes:
an insulating layer; and
the conductors located on the insulating layer.

3. The semiconductor device of claim 2, further comprising a third lead, wherein the third lead has a third surface facing one side in the thickness direction, and
wherein the first relay is mounted on the third surface.

4. The semiconductor device of claim 2, wherein the first relay is mounted on the first surface.

5. The semiconductor device of claim 1, wherein the second wires are connected to the conductors to which the first wires are connected.

6. The semiconductor device of claim 1, wherein the first wires are connected to the conductors.

7. The semiconductor device of claim 1, wherein the second wires are connected to the second leads.

8. The semiconductor device of claim 1, further comprising third wires connected to the conductors to which the first wires are connected,
wherein the conductive path further includes the third wires.

9. The semiconductor device of claim 2, wherein the first relay is located on one side of the semiconductor element in a first direction perpendicular to the thickness direction.

10. The semiconductor device of claim 3, wherein the third lead is located on one side of the first lead in a first direction perpendicular to the thickness direction, and
wherein the first relay is located on the third lead offset toward one side in the first direction when viewed in the thickness direction.

11. The semiconductor device of claim 10, further comprising:
a second relay located on the other side of the first relay in the first direction and mounted on the third surface; and
third wires,
wherein the first wires are connected to conductors of the second relay,
wherein the third wires are connected to the conductors of the second relay and the conductors of the first relay, and
wherein the conductive path further includes the third wires.

12. The semiconductor device of claim 9, wherein the second leads to which the second wires are connected are located on one side of the first relay in the first direction.

13. The semiconductor device of claim 9, wherein the second leads to which the second wires are connected are located apart from the first relay in a second direction perpendicular to the thickness direction and the first direction.

14. The semiconductor device of claim 2, wherein the insulating layer contains a semiconductor material.

15. The semiconductor device of claim 2, wherein the insulating layer contains ceramics.

16. The semiconductor device of claim 1, further comprising one or more fourth leads, wherein the conductors include the fourth leads.
